(19) United States
(12) Patent Application Publication
(10) Pub. No.: US 2007/0210448 A1
(43) Pub. Date: Sep. 13, 2007

(54) ELECTROLESS COBALT-CONTAINING LINER FOR MIDDLE-OF-THE-LINE (MOL) APPLICATIONS

(75) Inventors: Keith Kwong Hon Wong, Wappingers Falls, NY (US); Yun-Yu Wang, Poughquag, NY (US); Horatio S. Wildman, Wappingers Falls, NY (US); Christopher C. Parks, Poughkeepsie, NY (US); Chih-Chao Yang, Poughkeepsie, NY (US)

Correspondence Address: SCULLY SCOTT MURPHY & PRESSER, PC, 400 GARDEN CITY PLAZA, SUITE 300, GARDEN CITY, NY, 11530, US

(73) Assignee: INTERNATIONAL BUSINESS MACHINES CORPORATION, Armonk, NY (US)

(21) Appl. No.: 11/308,186

(22) Filed: Mar. 10, 2006

(51) Int. Cl. H01L 23/48

(52) U.S. Cl. 257/734

(57) ABSTRACT

A semiconductor structure that includes a Co-containing liner disposed between an oxygen-getter layer and a metal-containing conductive material is provided. The Co-containing liner, the oxygen-getter layer and the metal-containing conductive material form MOL metallurgy where the Co-containing liner replaces a traditional TiN liner. By “Co-containing” is meant that the liner includes elemental Co alone or elemental Co and at least one of P or B. In order to provide better step coverage of the inventive Co-containing liner within a high aspect ratio contact opening, the Co-containing liner is formed via an electroless deposition process.

### FIELD OF THE INVENTION

The present invention relates to a semiconductor structure and a method of fabricating the same. More particularly, the present invention relates to middle-of-the-line (MOL) metallurgy which interfaces the silicide contacts (source/drain and/or gates) to the interconnect structures as well as a method of fabricating such MOL metallurgy.

### BACKGROUND OF THE INVENTION

Tungsten (W) is widely used in the semiconductor industry as the middle-of-the-line (MOL) metallurgy interfacing silicide contacts of a semiconductor device or integrated circuit to overlying interconnect structures. The MOL metallurgy is typically formed within a patterned dielectric material (such as, for example, SiO₂) that has one or more contact openings that extend to the surface of each of the silicide contacts.

Due to the high aspect ratio (depth to width ratio of greater than 3) and small feature size (on the order of about 0.1 microns or less) of the contact openings formed into the dielectric material, W is deposited by a chemical vapor deposition (CVD) process, which usually includes WF₆ and a silane as precursors.

In such circumstances, W is deposited in a nucleation step (represented by Equation 1 below) and a bulk fill step (represented by Equation 2 below). It is observed that in the following equations, ‘g’ denotes a gas and ‘s’ denotes a solid.

During nucleation, the following reaction occurs:
2 WF₆ (g)+3 SiH₄ (g)→2 W (s)+3 SiF₄+6 H₂ (g) Equation 1

During the bulk fill processing step, the following reaction occurs:
WF₆ (g)+3 H₂ (g)→W (s)+6 HF (g) Equation 2

However, WF₆ is known to react with free silicon to form elemental tungsten and silane by way of the following reaction:
2 WF₆ (g)+3 Si (g)→2 W (s)+3 SiF₄ (g)+6 H₂ (g) Equation 3

Because of the reaction described by Equation 3, a liner must be deposited to protect silicon before the CVD W process. However, a liner is also needed to lower the contact resistance between the silicide contacts and W, and as an adhesive layer between CVD W and the dielectric material.

Many different types of liners are known and have been used in the prior art. One widely used liner is a Ti/CVD TiN stack. Ti is known to be a good oxygen ‘getter’ (that is, Ti has a high affinity for oxygen) and thus aids in cleaning up the surface oxide. However, excessive Ti is detrimental because it will react with WF₆ or HF forming volcanic eruption defects, which occur when Ti fluorides that are formed leave as volatile species. For some earlier technologies, and after Ti deposition, the liner stack was subjected to a forming gas anneal (for example, 550° C., 2 hour) to covert the excess Ti to TiN. However, this forming gas anneal is stripped down or eliminated for today's generation of high performance devices, particularly those using Ni mono-silicide because nickel mono-silicide will be transformed to the more resistance nickel disilicide when subjected to a high temperature anneal process.

One solution to overcome the reactive Ti issue is to increase the thickness of the CVD TiN. However, CVD TiN is a relatively high electrically resistive material, which typically has a sheet resistivity that is about 4 to 10 times greater than elemental Ti.

Since the ground rules or device geometry are becoming increasingly smaller and the contact opening aspect ratio is becoming greater, step coverage of TiN is also becoming a concern because decreased step coverage requires the TiN liner to be thick enough to ensure sufficient deposition within a contact opening.

In view of the above, there is a continued need to develop new MOL metallurgy that avoids the drawbacks mentioned above with prior art MOL metallurgy.

### SUMMARY OF THE INVENTION

The present invention provides a new MOL metallurgy wherein a Co-containing liner replaces the traditional TiN liner described above. By “Co-containing” is meant that the liner includes elemental Co alone or elemental Co and at least one of P or B. Optionally, W may also be used. Thus, the present invention provides a Co-containing liner that includes one of Co, CoP, CoWP, CoB, or CoWB. It is noted that the above-mentioned Co-containing liner functions as a fluorine barrier layer during deposition of CVD W and other like metal-containing conductive materials from a fluorine-containing metal precursor. In addition, the inventive Co-containing liner serves as a nucleation (i.e., seed) layer for an overlying metal-containing conductive material. Furthermore, the inventive Co-containing liner provides sufficient adhesion of the overlying metal-containing conductive material to an adjacent dielectric material.

In order to provide better step coverage of the inventive Co-containing liner within a high aspect ratio contact opening formed into a dielectric material, the Co-containing liner is formed via an electroless deposition process.

In broad terms, the present invention provides a semiconductor structure that includes the inventive Co-containing liner disposed between an oxygen-getter layer and a metal-containing conductive material. In some embodiments of the present invention, a diffusion barrier is optional disposed between the oxygen-getter layer and the Co-containing liner.

In general terms, the present invention provides a semiconductor structure that includes:
a semiconductor substrate having at least one semiconductor device located thereon, said
at least one semiconductor device including at least one silicide contact region;
a dielectric material disposed atop said semiconductor substrate and said at least one semiconductor device, said dielectric material having a contact opening that exposes each silicide contact region; and
metallurgy located within said contact opening that includes an oxygen-getter layer, a Co-containing liner disposed atop said oxygen-getter layer and an overlying metal-containing conductive material.

In some embodiments of the present invention, a diffusion barrier is optional disposed between the oxygen-getter layer and the Co-containing liner.

The semiconductor structure described above may also include one or more interconnect levels disposed atop said dielectric material, wherein each of said interconnect levels includes an interlevel dielectric having conductive features (lines, vias or combinations thereof) embedded therein. The embedded conductive features within the interconnect levels may also include the inventive metallurgy described above.

In addition to providing the aforementioned semiconductor structures, the present invention also provides a method of forming the same.

In broad terms, the method of the present invention includes depositing a Co-containing liner between an oxygen-getter layer and a metal-containing conductive material, wherein said Co-containing liner is deposited by electroless deposition. In some embodiments of the present invention, a diffusion barrier is optional disposed between the oxygen-getter layer and the Co-containing liner.

In general terms, the method of the present invention includes:
providing a semiconductor substrate having at least one semiconductor device located thereon, said at least one semiconductor device including at least one silicide contact region;
forming a dielectric material atop said semiconductor substrate and said at least one semiconductor device, said dielectric material having a contact opening that exposes each silicide contact region;
forming an oxygen-getter layer within said contact opening;
forming a Co-containing liner on said oxygen-getter layer by electroless deposition; and filling the contact opening with a metal-containing conductive material.

In some embodiments of the present invention, a diffusion barrier is optional disposed between the oxygen-getter layer and the Co-containing liner.

The general method described above may also include forming one or more interconnect levels atop said dielectric material, wherein each of said interconnect levels includes an interlevel dielectric having conductive features (lines, vias or combinations thereof) embedded therein. In accordance with the present invention, conductive features embedded within the interlevel dielectrics may include the inventive metallurgy.

### BRIEF DESCRIPTION OF THE DRAWINGS

FIGS. 1A-1E are pictorial representations (through cross sectional views) depicting the basic processing steps of the present invention up to, but not including interconnect formation.

FIG. 2 is a pictorial representation (through a cross sectional view) depicting the structure of FIG. 1E including at least one interconnect level disposed thereon.

### DETAILED DESCRIPTION OF THE INVENTION

The present invention, which provides an electroless Co-containing liner for MOL applications, will now be described in greater detail by referring to the following description and drawings that accompany the present application. It is noted that the drawings of the present application are provided for illustrative purposes and, as such, they are not drawn to scale.

In the following description, numerous specific details are set forth, such as particular structures, components, materials, dimensions, processing steps and techniques, in order to provide a thorough understanding of the present invention. However, it will be appreciated by one of ordinary skill in the art that the invention may be practiced without these specific details. In other instances, well-known structures or processing steps have not been described in detail in order to avoid obscuring the invention.

As stated above, the present invention provides MOL metallurgy wherein a Co-containing liner replaces the traditional TiN liner described above. By “Co-containing” is meant that the liner includes elemental Co alone or elemental Co and at least one of P or B. Optionally, W may also be used. Thus, the present invention provides a Co-containing liner that includes one of Co, CoP, CoWP, CoB, or CoWB. It is noted that the above-mentioned Co-containing liner functions as a fluorine barrier layer during deposition of CVD W and other like metal-containing conductive materials from a fluorine-containing metal precursor. In addition, the inventive Co-containing liner serves as a nucleation (i.e., seed) layer for an overlying metal-containing conductive material. Furthermore, the inventive Co-containing liner provides sufficient adhesion of the overlying metal-containing conductive material to an adjacent dielectric material. In order to provide better step coverage of the inventive Co-containing liner within a high aspect ratio (depth to width ratio of greater than 3, preferably greater than 5) contact opening formed into a dielectric material, the Co-containing liner is formed via an electroless deposition process.

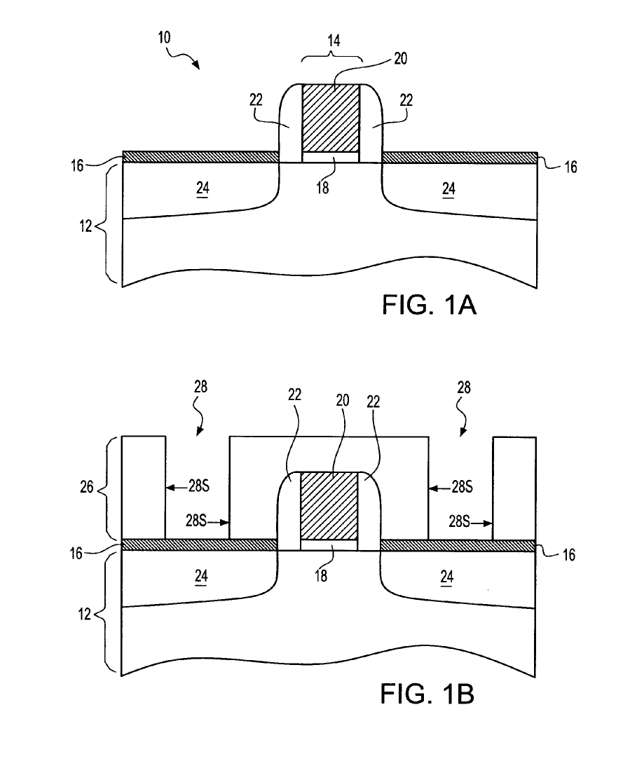

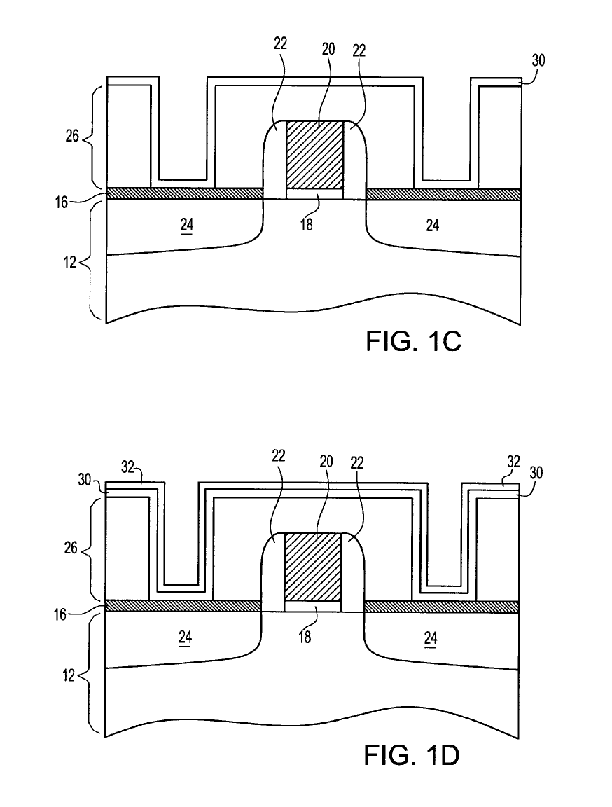

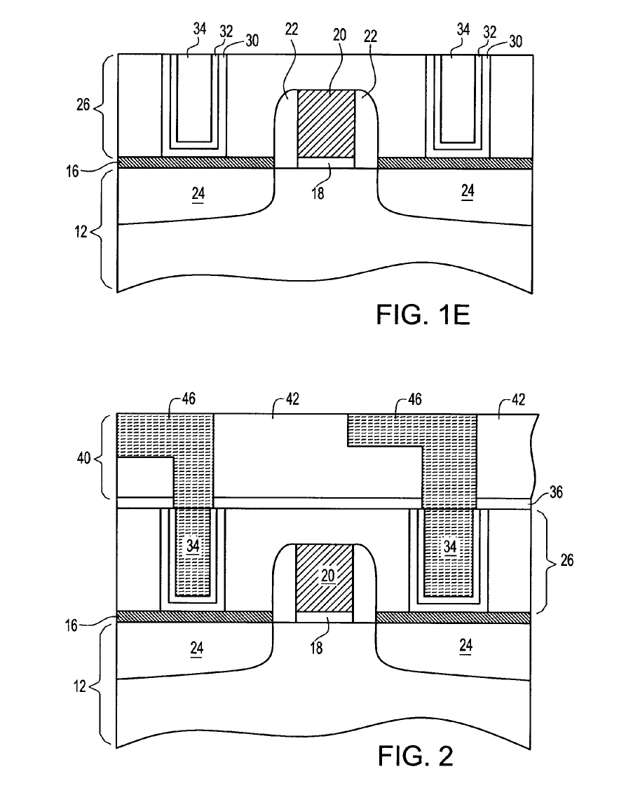

Reference is first made to FIG. 1A which illustrates an initial structure 10 that can be employed in the present invention. The initial structure 10 includes a semiconductor substrate 12 having at least one semiconductor device 14 located thereon. In accordance with the present invention, the at least one semiconductor device 14 includes at least one silicide contact region 16. It is noted that in the drawings, the one semiconductor device 14 is depicted as a field effect transistor. Although such a semiconductor device is depicted and illustrated, the present invention also contemplates other semiconductor devices including, for example, capacitors, diodes, bipolar transistors, BiCMOS devices, memory devices and the like which include at least one silicide contact region. It is further noted that in the embodiment illustrated, the at least one silicide contact region 16 is located atop the source/drain diffusion regions of the field effect transistor. Although such a location is specifically illustrated, the present invention also contemplates cases where the at least one silicide contact region 16 is located atop other material layers that are disposed on the semiconductor substrate 12. For example, atop the gate conductor, or atop a conductive plate of a capacitor.

The term “semiconductor substrate” is used throughout this application to denote any semiconducting material including, for example, Si, SiGe, SiGeC, SiC, Ge alloys, GaAs, InAs, InP and other III/V or II/VI compound semiconductors. In addition to these listed types of semiconducting materials, the present invention also contemplates cases in which the semiconductor substrate 12 is a layered semiconductor such as, for example, Si/SiGe, Si/SiC, silicon-on-insulators (SOIs) or silicon germanium-on-insulators (SGOIs). In some embodiments of the present invention, it is preferred that the semiconductor substrate 12 be composed of a Si-containing semiconductor material, i.e., a semiconductor material that includes silicon. The semiconductor substrate 12 may be doped, undoped or contain doped and undoped regions therein.

It is also noted that the semiconductor substrate 12 may be strained, unstrained or contain strained regions and unstrained regions therein. The semiconductor substrate 12 may also have a single crystal orientation or alternatively, the substrate 12 may be a hybrid semiconductor substrate that has surface regions having different crystallographic orientations. The semiconductor substrate 12 may also have one or more isolation regions such as, for example, trench isolation regions or field oxide isolation regions, located therein.

Next, the at least one semiconductor device 14 including at least one silicide contact region 16 is formed. The at least one semiconductor device 14 is formed utilizing conventional techniques that are well known to those skilled in the art. The processing details may vary depending on the type of device being fabricating. In the case of a field effect transistor, deposition, lithography, etching and ion implantation can be used in forming the field effect transistor. Alternatively, a replacement gate process can be used in forming the field effect transistor.

As shown, each field effect transistor includes a gate dielectric 18, a gate conductor 20, an optional offset spacer 22, and source/drain regions 24. The gate dielectric 18, the gate conductor 20 and the optional offset spacer 22 are comprised of conventional materials. For example, the gate dielectric 18 is comprised of an oxide, nitride, oxynitride or combinations and multilayers thereof. The gate conductor 20 is comprised of polysi, SiGe, an elemental metal, an alloy including an elemental metal, a metal silicide, a metal nitride or any combination including multilayers thereof. The optional offset spacer 22 is comprised of an oxide, a nitride, an oxynitride or any combination, including multilayers thereof. The source/drain regions 24 are formed within the semiconductor substrate 12 or within a semiconducting layer disposed on the substrate.

The at least one silicide contact region 16 is formed utilizing a standard salicidation (‘self-aligned’) process well known in the art. This includes forming a metal capable of reacting with silicon atop the entire structure, forming a barrier layer atop the metal, heating the structure to form a silicide, removing non-reacted metal and the barrier layer and, if needed, conducting a second heating step. When silicon is not present, a layer of a Si-containing material can be formed prior to forming the metal. The second heating step is required in those instances in which the first heating step does not form the lowest resistance phase of the silicide. Note that if the gate conductor 20 is comprised of polysilicon or SiGe and no dielectric cap is present, this step of the present can be used in forming a metal silicide atop the gate conductor 20. This particular embodiment is not shown in the drawings. The metal used in forming the silicide comprises one of Ti, Ni, Pt, W, Co, Ir, and the like. Alloying additives can also be present as desired. The silicide heating, i.e., anneal, step utilizes conditions that are well known to those skilled in the art.

After providing the initial structure 10 shown in FIG. 1A, a dielectric material 26 including at least one contact opening 28 is formed thereon. As shown, the at least one contact opening 28 exposes an upper surface of the silicide contact region 16. The resultant structure including the dielectric material 26 and the one contact opening 28 is shown, for example, in FIG. 1B.

The dielectric material 26 may comprise any dielectric used in middle-of-the-line (MOL) applications. The dielectric material 26 may be porous or non-porous. Some examples of suitable dielectrics that can be used as the dielectric material 26 include, but are not limited to: SiO₂, a doped or undoped silicate glass, C doped oxides (i.e., organosilicates) that include atoms of Si, C, O and H, thermosetting polyarylene ethers, or multilayers thereof, silicon nitride, silicon oxynitride or any combination, including multilayers thereof. The term “polyarylene” is used in this application to denote aryl moieties or inertly substituted aryl moieties which are linked together by bonds, fused rings, or inert linking groups such as, for example, oxygen, sulfur, sulfone, sulfoxide, carbonyl and the like. Preferably, the dielectric material 26 is SiO₂ that is formed from a TEOS (tetraethylorthosilane) precursor.

The dielectric material 26 typically has a dielectric constant that is about 4.0 or less, with a dielectric constant of about 2.8 or less being even more typical. The thickness of the dielectric material 26 may vary depending upon the dielectric material used. Typically, and for normal MOL applications, the dielectric material 26 has a thickness from about 200 to about 450 nm.

The at least one contact opening 28 that is present within the dielectric material 26 is formed by lithography and etching. The lithographic process includes forming a photoresist (not shown) atop the dielectric material 26, exposing the photoresist to a desired pattern of radiation and developing the exposed photoresist utilizing a conventional resist developer. The etching process includes a dry etching process (such as, for example, reactive ion etching, ion beam etching, plasma etching or laser ablation), or a wet chemical etching process that selectively removes the exposed dielectric material 26. Typically, reactive ion etching is used in providing the at least one contact opening 28. After etching, the photoresist is typically removed utilizing a conventional resist stripping process well known to those skilled in this art. As shown, the contact opening 28 has sidewalls 28s. The sidewalls 28s within the contact opening 28 may be substantially vertical, as shown, or some tapering may be evident. The contact opening 28 typically has an aspect ratio that is greater than 3, preferably greater than 5.

At this point of the inventive process, the exposed surface of the at least one silicide contact region 16 as well the wall surfaces within the contact opening 28 are subjected to a treatment process that is capable of removing any surface oxide or etch residue that may be present thereon. Suitable treatment processes that can be employed in the present invention include, for example, Ar sputtering and/or contacting with a chemical etchant. Some negligible widening of the contact opening 28 may occur during this step of the present invention.

Next, and as shown in FIG. 1C, an oxygen-getter layer 30, which may comprise Ti, W, or any other material that has a high affinity for oxygen, is formed. The oxygen-getter layer 30 is formed within the contact opening 28 on the exposed wall portions thereof as well as atop the exposed horizontal surface of the dielectric material 26 itself. The oxygen-getter layer 30 is formed by a deposition process such as, for example, atomic layer deposition (ALD), chemical vapor deposition (CVD), plasma enhanced chemical vapor deposition (PECVD), physical vapor deposition (PVD), sputtering, chemical solution deposition, or plating. Typically, the oxygen-getter layer 30 is comprised of Ti.

The thickness of the oxygen-getter layer 30 may vary depending on the exact means of the deposition process used as well as the material employed. Typically, the oxygen-getter layer 30 has a thickness from about 2 to about 40 nm, with a thickness from about 5 to about 10 nm being more typical.

Next, an optional diffusion barrier (not specifically shown in the drawings), which may comprise Ta, TaN, TiN, Ru, RuN, WN or any other material that can serve as a barrier to prevent conductive material from diffusing there through, may be formed. The optional diffusion barrier is formed within the contact opening 28 on surface of the oxygen-getter layer 30. The optional diffusion barrier is formed by a deposition process such as, for example, atomic layer deposition (ALD), chemical vapor deposition (CVD), plasma enhanced chemical vapor deposition (PECVD), physical vapor deposition (PVD), sputtering, chemical solution deposition, or plating. The thickness of the optional diffusion barrier may vary and is within ranges that are well known to those skilled in the art. The optional diffusion barrier can be omitted when W is employed as the conductive metal. When Cu or Al is employed, the optional diffusion barrier is typically employed.

Following formation of the oxygen-getter layer 30 and the optional diffusion barrier, the inventive Co-containing liner 32 is formed atop the oxygen-getter layer 30 (when no diffusion barrier is present) or atop the optional diffusion barrier (when present). The resultant structure assuming that the optional diffusion barrier is omitted is shown, for example, in FIG. 1D. The Co-containing liner 32 comprises elemental Co alone, or elemental Co and at least one of P or B. Optionally, W may also be used. Thus, the present invention provides a Co-containing liner 32 that includes one of Co, CoP, CoWP, CoB, or CoWB. Of these materials, CoP or CoWP are preferred materials for the Co-containing liner 32.

The thickness of the Co-containing liner 32 may vary depending on the exact conditions of the electroless deposition process employed. In general, the thickness of the Co-containing liner 32 is from about 1 to about 20 nm, with a thickness from about 4 to about 10 nm being even more typical.

In accordance with the present invention, the Co-containing liner 32 functions as a fluorine barrier layer during deposition of CVD W and other like metal-containing conductive materials from a fluorine-containing metal precursor. In addition, the Co-containing liner 32 serves as a nucleation (i.e., seed) layer for an overlying metal-containing conductive material. Furthermore, the Co-containing liner 32 provides sufficient adhesion of the overlying metal-containing conductive material to an adjoining dielectric material. In order to provide better step coverage of the Co-containing liner 32 within the contact opening 28, the Co-containing liner 32 is formed via an electroless deposition process.

Metal deposition by electroless plating is well practiced in industry. In an electroless deposition process, a redox reaction involving the oxidation of one or more soluble reducing agent(s) and the reduction of one or more metallic ions occurs on the surface of a substrate. For many metals including Cu, Ni, Co, Au, Ag Pd, Rh, the freshly deposited surface is sufficiently catalytic for the process to continue.

In electroless plating, activation of a surface, non conductive, or semiconductor can be achieved by the incorporation onto the top surface layer of nanometer sized catalytic particles. These catalytic particles can be either Pd, Co, Ni, and they can be applied by a either physical or chemical deposition.

The function of these particles is to catalyze and initiate the electrochemical deposition reaction when the substrate is immersed into an electroless plating bath. The electroless plating bath deposits a conductive layer on the catalyzed area of the substrate, the thickness of the plating layer depending mainly on the time of exposure to the plating bath. A suitable electroless plating system used in this invention is based on the use of the hypophosphite reducing agent. In this system, a mixture of hypophosphite ions and cobalt ions is made together with citrate stabilizing agent, at a suitable pH and temperature (usually between 65° to 75° C.). When the activated catalyzed substrate described above is immersed on this plating bath, the following reaction occurs on the substrate:
Co²⁺+2H₂PO₂⁻ [symbol] Co metal+2HPO₃⁻+2H⁺

The Co metal is then deposited selectively on top of the catalyzed Pd layer on the substrate. The metal deposited by this reaction, can be either Co, CoP, CoWP, CoB or CoWB, depending on the composition of the plating bath solution. The catalytic layer can be either Pd, Co or Ni metal. The catalytic Pd layer can be incorporated on the surface of the substrate either by ion implantation, or other type of physical deposition method, or it can be applied by chemical means. For example, a colloidal Pd catalytic solution containing microparticles of Pd in suspension can be injected in the inside of the contact openings and it will deposit the Pd particles with very good adhesion onto the inside of the contact opening.

The remaining region of the contact opening 28 is filled with a metal-containing conductive material 34, which together with the oxygen-getter layer 30 and the Co-containing liner 32 form the MOL metallurgy of the present invention. The MOL metallurgy of the present invention may also include an optional diffusion barrier located between the oxygen-getter layer 30 and the Co-containing liner 32. The metal-containing conductive material 34 used in forming the inventive MOL metallurgy includes, for example, a conductive metal, an alloy comprising at least one conductive metal, a metal silicide or combinations thereof. Preferably, the metal-containing conductive material 34 that is used in forming the inventive metallurgy for MOL applications includes a conductive metal such as Cu, W or Al, with Cu or a Cu alloy (such as AlCu) being highly preferred in the present invention. The conductive material is filled into the remaining opening utilizing a conventional deposition process including, but not limited to: CVD, PECVD, sputtering, chemical solution deposition or plating. Although these various deposition processes can be employed, CVD utilizing a fluorine-containing metal precursor and a silane are typically used.

After deposition, a conventional planarization process such as, for example, chemical mechanical polishing (CMP) can be used to provide a planarized structure such as is illustrated in FIG. 1E. It is again emphasized that the inventive metallurgy for MOL applications includes the oxygen-getter layer 30, optionally the diffusion barrier, the Co-containing liner 32 and the metal-containing conductive material 34.

After forming the structure shown in FIG. 1E, a dielectric capping layer 36 is typically formed on the surface of the structure shown in FIG. 1E utilizing a conventional deposition process such as, for example, CVD, PECVD, chemical solution deposition, or evaporation. The dielectric capping layer 36 comprises any suitable dielectric capping material such as, for example, SiC, Si₄NH₃, SiO₂, a carbon doped oxide, a nitrogen and hydrogen doped silicon carbide SiC(N,H) or multilayers thereof. The thickness of the capping layer 36 may vary depending on the technique used to form the same as well as the material make-up of the layer. Typically, the capping layer 36 has a thickness from about 15 to about 55 nm, with a thickness from about 25 to about 45 nm being more typical.

Next, an interconnect level 40 is formed by applying an interlevel dielectric material 42 to the upper exposed surface of the capping layer 36. The interlevel dielectric material 42 may comprise the same or different, preferably the same, dielectric as that of the dielectric material 26. The processing techniques and thickness ranges for the dielectric material 26 are also applicable here for the interlevel dielectric material 42. Next, at least one opening is formed into the interlevel dielectric material 42 utilizing lithography, as described above, and etching. The etching may comprise a dry etching process, a wet chemical etching process or a combination thereof. Typically, the opening consists of a lower via opening and an upper line opening. A conventional via-before-line or a line-before-via process can be used.

In the instances when a via opening and a line opening are formed, the etching step also removes a portion of the dielectric capping layer 36 that is located atop the inventive metallurgy shown in FIG. 1E in order to make electrical contact between these materials.

Next, a conductive region 46 including for example, a diffusion barrier, a plating seed layer, and a conductive material are formed within the opening utilizing conventional interconnect processing that is well known in the art. The resultant structure is shown in FIG. 2. In some embodiments, the inventive metallurgy described above can be formed into the opening present in the interlevel dielectric material 42.

The present invention contemplates a structure in which a closed-via bottom structure is present. In such a structure, the diffusion barrier of the interconnect level is disposed between the inventive MOL metallurgy and the interconnect conductive material. Open-via and anchored-via structures are also contemplated. An open-via structure is formed by removing the diffusion barrier of the interconnect structure from the bottom of via utilizing ion bombardment or another like directional etching process prior to deposition of the other elements. The anchored-via bottom structure is formed by first etching a recess into the inventive MOL metallurgy utilizing a selective etching process. The diffusion barrier of the interconnect structure is then formed and it is selectively removed from the bottom portion of the via and recessed by utilizing one of the above-mentioned techniques. The other elements of the interconnect structure are then formed within the opening as described herein.

While the present invention has been particularly shown and described with respect to preferred embodiments thereof, it will be understood by those skilled in the art that the foregoing and other changes in forms and details may be made without departing from the spirit and scope of the present invention. It is therefore intended that the present invention not be limited to the exact forms and details described and illustrated, but fall within the scope of the appended claims.

What is claimed is:

1. A semiconductor structure comprising a Co-containing liner disposed between an oxygen-getter layer and a metal-containing conductive material.

2. The semiconductor structure of claim 1 wherein said Co-containing liner comprises elemental Co, or elemental Co and at least one of P or B.

3. The semiconductor structure of claim 2 wherein said Co-containing liner further comprises W.

4. The semiconductor structure of claim 1 wherein said Co-containing liner comprises at least one of CoP or CoWP.

5. The semiconductor structure of claim 1 wherein said oxygen-getter layer comprises Ti or W.

6. The semiconductor structure of claim 1 wherein said metal-containing conductive material comprises a conductive metal, an alloy including a conductive metal, a metal silicide or any combination thereof.

7. The semiconductor structure of claim 1 wherein said oxygen-getter layer comprises Ti, said Co-containing liner comprises CoWP and said metal-containing conductive material comprises Cu or a Cu-containing alloy.

8. A semiconductor structure comprising:
a semiconductor substrate having at least one semiconductor device located thereon, said
at least one semiconductor device including at least one silicide contact region;
a dielectric material disposed atop said semiconductor substrate and said at least one semiconductor device, said dielectric material having a contact opening that exposes each silicide contact region; and
metallurgy located within said contact opening that includes an oxygen-getter layer, a Co-containing liner disposed atop said oxygen-getter layer and an overlying metal-containing conductive material.

9. The semiconductor structure of claim 8 wherein said Co-containing liner comprises Co, optionally at least one of P or B, and further optionally W.

10. The semiconductor structure of claim 8 wherein said Co-containing liner comprises at least one of CoP or CoWP.

11. The semiconductor structure of claim 8 wherein said oxygen-getter layer comprises Ti or W.

12. The semiconductor structure of claim 8 wherein said metal-containing conductive material comprises a conductive metal, an alloy including a conductive metal, a metal silicide or any combination thereof.

13. The semiconductor structure of claim 8 wherein said oxygen-getter layer comprises Ti, said Co-containing liner comprises CoWP and said metal-containing conductive material comprises Cu or a Cu-containing alloy.

14. The semiconductor structure of claim 8 further comprising at least one interlevel dielectric having at least one conductive feature embedded therein disposed on said dielectric material including said metallurgy.

15. The semiconductor structure of claim 8 wherein said at least one semiconductor device is a field effect transistor.

16. The semiconductor structure of claim 8 wherein said silicide contact region is located atop source/drain regions of a field effect transistor and optionally atop a gate conductor of a field effect transistor.

17. A method of forming a semiconductor structure comprising:
depositing a Co-containing liner between an oxygen-getter layer and a metal-containing conductive material, wherein said Co-containing liner is deposited by electroless deposition.

18. The method of claim 17 wherein said electroless deposition using catalytic particles of Pd, Co or Ni.

19. The method of claim 17 wherein said Co-containing liner comprises Co, optionally at least one of P or B, and further optionally W.

20. The method of claim 17 wherein said Co-containing liner comprises at least one of CoP or CoWP.

21. The method of claim 17 wherein said oxygen-getter layer comprises Ti or W.

22. The method of claim 17 wherein said metal-containing conductive material comprises a conductive metal, an alloy including a conductive metal, a metal silicide or any combination thereof.

23. The method of claim 17 wherein said oxygen-getter layer comprises Ti, said Co-containing liner comprises CoWP and said metal-containing conductive material comprises Cu or a Cu-containing alloy.

24. A method of forming a semiconductor structure comprising:
providing a semiconductor substrate having at least one semiconductor device located thereon, said at least one semiconductor device including at least one silicide contact region;
forming a dielectric material atop said semiconductor substrate and said at least one semiconductor device, said dielectric material having a contact opening that exposes each silicide contact region;
forming an oxygen-getter layer within said contact opening;
forming a Co-containing liner on said oxygen-getter layer by electroless deposition; and
filling the contact opening with a metal-containing conductive material.

25. The method of claim 24 wherein said electroless deposition using catalytic particles of Pd, Co or Ni.

26. The method of claim 24 wherein said Co-containing liner comprises Co, optionally at least one of P or B, and further optionally W.

27. The method of claim 24 wherein said oxygen-getter layer comprises Ti or W.

28. The method of claim 24 wherein said metal-containing conductive material comprises a conductive metal, an alloy including a conductive metal, a metal silicide or any combination thereof.

29. The method of claim 24 wherein said oxygen-getter layer comprises Ti, said Co-containing liner comprises CoWP and said metal-containing conductive material comprises Cu or a Cu-containing alloy.

30. The method of claim 24 further comprising forming at least one interlevel dielectric having at least one conductive feature embedded therein atop said dielectric material including said metallurgy.
